(19) United States
(12) Patent Application Publication
(10) Pub. No.: US 2026/0068687 A1
(43) Pub. Date: Mar. 5, 2026

(54) SEMICONDUCTOR PACKAGE

(71) Applicant: Samsung Electronics Co., Ltd., Suwon-si (KR)

(72) Inventors: Daeseo PARK, Suwon-si (KR); Wonil LEE, Suwon-si (KR)

(73) Assignee: Samsung Electronics Co., Ltd., Suwon-si (KR)

(21) Appl. No.: 19/278,975

(22) Filed: Jul. 24, 2025

(30) Foreign Application Priority Data
Aug. 27, 2024 (KR) 10-2024-0115256

(51) Int. Cl. H01L 23/544; H01L 23/00; H01L 23/48

(52) U.S. Cl. CPC H01L 23/544

(57) ABSTRACT

A semiconductor package includes a first semiconductor chip including a first semiconductor substrate and a first wiring structure including a first wiring pattern and a first wiring insulating film, a second semiconductor chip including a second semiconductor substrate and a second wiring structure including a second wiring pattern and a second wiring insulating film, a first bonding pad on the first wiring structure, a first passivation layer surrounding a side surface of the first bonding pad, a second bonding pad electrically connected to the first bonding pad, a second passivation layer surrounding a side surface of the second bonding pad, a first alignment inspection structure horizontally apart from the first wiring pattern and penetrating the first passivation layer, and a second alignment inspection structure vertically penetrating the second semiconductor substrate, the second wiring insulating film, and the second passivation layer.

### CROSS-REFERENCE TO RELATED APPLICATIONS

This application is based on and claims priority under 35 U.S. C. § 119 to Korean Patent Application No. 10-2024-0115256, filed on Aug. 27, 2024, in the Korean Intellectual Property Office, the disclosure of which is incorporated by reference herein in its entirety.

### BACKGROUND

The inventive concepts relate to semiconductor packages.

With the progress in the electronics industry, the demand for high integration of semiconductor devices is increasing. Accordingly, various problems, such as the decrease in the process margin of the exposure process that defines fine patterns, are occurring, making it increasingly difficult to implement semiconductor devices. Recently, as the development of a 3-dimensional (3D) semiconductor package, which is a single semiconductor chip having mounted thereon multiple semiconductor chips, has become active, through silicon vias (TSV), which form vertical electrical connections by penetrating a substrate or die, are being used. Accordingly, there is a need for technology that can secure electrical and mechanical reliability of the connection structure between multiple semiconductor chips.

### SUMMARY

The inventive concepts provide semiconductor packages with improved reliability.

The objectives to be solved by the inventive concepts are not limited to the objectives above, and other objectives will be clearly understood by those skilled in the art from the description below.

According to some aspects of the inventive concepts, there is provided a semiconductor package including a first semiconductor chip including a first semiconductor substrate and a first wiring structure including a first wiring pattern and a first wiring insulating film, a second semiconductor chip including a second semiconductor substrate and a second wiring structure including a second wiring pattern and a second wiring insulating film, a first bonding pad on the first wiring structure, a first passivation layer surrounding a side surface of the first bonding pad, a second bonding pad electrically connected to the first bonding pad, a second passivation layer surrounding a side surface of the second bonding pad, a first alignment inspection structure horizontally apart from the first wiring pattern and penetrating the first passivation layer, and a second alignment inspection structure vertically penetrating the second semiconductor substrate, the second wiring insulating film, and the second passivation layer.

According to some aspects of the inventive concepts, there is provided a semiconductor package including a first semiconductor chip including a first semiconductor substrate and a first wiring structure, a second semiconductor chip including a second semiconductor substrate and a second wiring structure, a first bonding pad and a first inspection pad on the first wiring structure, a first passivation layer surrounding a side surface of the first bonding pad and a side surface of the first inspection pad, a second bonding pad electrically connected to the first bonding pad and a second inspection pad electrically connected to the first inspection pad, a second passivation layer surrounding a side surface of each of the second bonding pad and the second inspection pad, and a second inspection electrode penetrating the second wiring structure and the second semiconductor substrate and in direct contact with the second inspection pad.

According to some aspects of the inventive concepts, there is provided a semiconductor package including a first semiconductor chip including a first semiconductor substrate and a first wiring structure including a first wiring pattern and a first wiring insulating film, a second semiconductor chip stacked on the first semiconductor chip and including a second semiconductor substrate and a second wiring structure, the second wiring structure including a second wiring pattern and a second wiring insulating film, a first bonding pad on the first semiconductor chip and a first passivation layer surrounding the first bonding pad, a second bonding pad on the second semiconductor chip opposite to the first bonding pad, and a second passivation layer surrounding the second bonding pad, a first inspection electrode vertically penetrating the first semiconductor substrate, the first wiring structure, and the first passivation layer, and a second inspection electrode vertically penetrating the second semiconductor substrate, the second wiring structure, and the second passivation layer, and electrically connected to the first inspection electrode.

### BRIEF DESCRIPTION OF THE DRAWINGS

Example embodiments will be more clearly understood from the following detailed description taken in conjunction with the accompanying drawings in which:

FIG. 1 is a schematic plan view to describe a semiconductor package according to some example embodiments;

FIGS. 2A and 2B are schematic cross-sectional views to describe semiconductor packages according to some example embodiments;

FIG. 3 is a schematic cross-sectional view to describe a semiconductor package according to some example embodiments;

FIGS. 4A and 4B are schematic cross-sectional views to describe semiconductor packages according to some example embodiments;

FIG. 5 is a schematic cross-sectional view to describe a semiconductor package according to some example embodiments;

FIG. 6 is a schematic plan view to describe a semiconductor package according to some example embodiments;

FIG. 7 is a schematic enlarged plan view to describe a semiconductor package according to some example embodiments; and FIGS. 8A, 8B, and 8C are schematic enlarged plan views to describe semiconductor packages according to some example embodiments.

### DETAILED DESCRIPTION OF THE EMBODIMENTS

Hereinafter, example embodiments will be described in detail with reference to the attached drawings. The same reference symbols are used for identical components in the drawings, and repeated descriptions thereof are omitted.

In some example embodiments below, the terms ‘first, second,’ etc. are not used in a limiting sense but are used for the purpose of distinguishing one component from another.

In some example embodiments below, singular expressions include plural expressions unless the context clearly indicates otherwise.

In the drawings, the sizes of components may be exaggerated or reduced for convenience of description. For example, the size and thickness of each component shown in the drawing are arbitrarily shown for convenience of description, and thus the inventive concepts are not necessarily limited to what is shown.

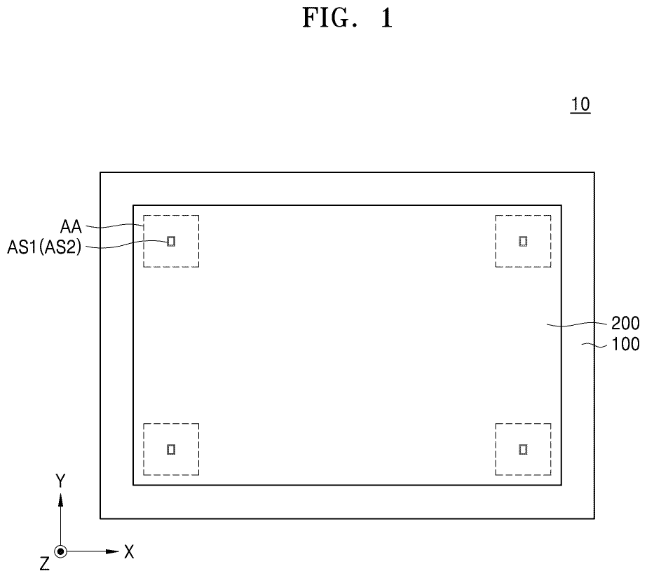

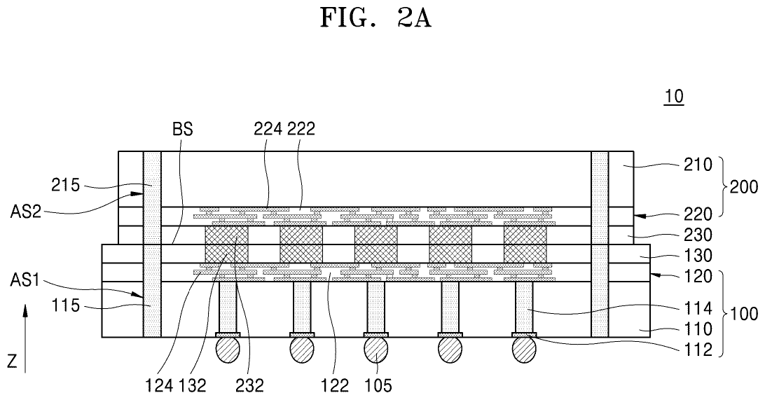

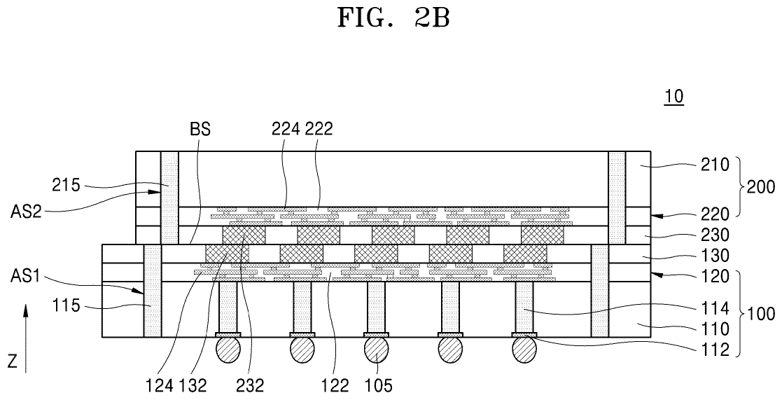

FIG. 1 is a schematic plan view to describe a semiconductor package according to some example embodiments, and FIGS. 2A and 2B are schematic cross-sectional views to describe semiconductor packages according to some example embodiments.

Referring to FIGS. 1 and 2A, a semiconductor package 10 according to some example embodiments may include a first semiconductor chip 100, a first passivation layer 130, a second passivation layer 230, a second semiconductor chip 200, a first alignment inspection structure AS1, and a second alignment inspection structure AS2.

The first semiconductor chip 100 and the second semiconductor chip 200 may be memory semiconductor chips. Examples of the memory semiconductor chips may be a volatile memory semiconductor chip, such as, for example, dynamic random-access memory (DRAM), or static random-access memory (SRAM), or nonvolatile memory semiconductor chip, such as phase-change random access memory (PRAM), magnetoresistive random access memory (MRAM), ferroelectric random-access memory (FeRAM), or resistive random-access memory (RRAM). The first semiconductor chip 100 may be, for example, a buffer semiconductor chip.

Alternatively, the first semiconductor chip 100 may be a logic semiconductor chip and the second semiconductor chip 200 may be a memory semiconductor chip. The first semiconductor chip 100 may be a controller semiconductor chip that controls input/output operations of the second semiconductor chip 200 electrically connected to the first semiconductor chip 100.

The first semiconductor chip 100 may include a first semiconductor substrate 110, a first connection pad 112, a first through electrode 114, and a first wiring structure 120. The second semiconductor chip 200 may include a second semiconductor substrate 210 and a second wiring structure 220.

The first semiconductor substrate 110 and the second semiconductor substrate 210 may each be, for example, bulk silicon or silicon-on-insulator (SOI). Alternatively, the first semiconductor substrate 110 and the second semiconductor substrate 210 may each be a silicon substrate, or may include other materials, such as, but not limited to, silicon germanium, silicon germanium on insulator (SGOI), indium antimonide, lead tellurium compound, indium arsenide, indium phosphide, gallium arsenide, or gallium antimonide.

The first connection pad 112 may be arranged on a lower surface of the first semiconductor chip 100. The first connection pad 112 may be arranged, for example, on a lower surface of the first semiconductor substrate 110 in a vertical direction (Z direction). The first connection pad 112 may include, for example, but is not limited to, at least one of aluminum (Al), copper (Cu), nickel (Ni), tungsten (W), platinum (Pt), gold (Au), and a combination thereof.

A first connection terminal 105 may be arranged on the first connection pad 112. The first connection terminal 105 may be electrically connected to the first connection pad 112. The first connection terminal 105 may have various shapes, such as a pillar structure, a ball structure, or a solder layer.

The first through electrode 114 may penetrate the first semiconductor substrate 110. The first through electrode 114 may have, for example, a columnar shape extending in the vertical direction (Z direction). The first through electrode 114 may be electrically connected to the first connection pad 112 and the first wiring structure 120.

The first through electrode 114 may include, for example, a barrier film formed on a columnar surface and a buried conductive layer filling the inside of the barrier film. The barrier film may include at least one of Ti, TiN, Ta, TaN, Ru, Co, Mn, WN, Ni, and NiB, but is not limited thereto. The buried conductive layer may include, but is not limited to, at least one of Cu, a Cu alloy such as CuSn, CuMg, CuNi, CuZn, CuPd, CuAu, CuRe, or CuW, W, W alloy, Ni, Ru, and Co.

For example, an insulating film may be between the first semiconductor substrate 110 and the first through electrode 114. The insulating film may include, but is not limited to, an oxide film, a nitride film, a carbide film, a polymer, or a combination thereof.

The first wiring structure 120 may be arranged on the first semiconductor substrate 110. For example, the first wiring structure 120 may be arranged on an upper surface of the first semiconductor substrate 110 in the vertical direction (Z direction). The first wiring structure 120 may include a first wiring insulating film 122 and a first wiring pattern 124 within the first wiring insulating film 122. The first wiring pattern 124 may be sequentially stacked from an upper surface of the first semiconductor substrate 110.

The first wiring structure 120 may include a first wiring area in which the first wiring pattern 124 is arranged and a first alignment area in which the first wiring pattern 124 is not arranged. The first wiring area may be positioned between the first alignment areas.

The first passivation layer 130 and a first bonding pad 132 may be arranged on the first wiring structure 120. The first passivation layer 130 may surround at least a portion of each of a side surface of the first bonding pad 132 and a side surface of a first inspection electrode 115 described below. The first bonding pad 132 may overlap the first wiring pattern 124 in the vertical direction (Z direction). The first bonding pad 132 may be electrically connected to the first wiring pattern 124.

The second semiconductor chip 200 may be arranged above the first semiconductor chip 100. The second semiconductor chip 200 may be spaced apart from the first semiconductor chip 100 in the vertical direction (Z direction).

The second wiring structure 220 may be arranged on the second semiconductor substrate 210. The second wiring structure 220 may face the first wiring structure 120. The second wiring structure 220 may be face, for example, the first wiring structure 120 in the vertical direction (Z direction).

The second wiring structure 220 may include a second wiring insulating film 222 and a second wiring pattern 224 in the second wiring insulating film 222. The second wiring pattern 224 may be sequentially stacked from a lower surface of the second semiconductor substrate 210.

The second wiring structure 220 may include a second wiring area in which the second wiring pattern 224 is arranged and a second alignment area in which the second wiring pattern 224 is not arranged. The second wiring area may be positioned between the second alignment areas.

The second alignment area of the second wiring structure 220 may overlap the first alignment area of the first wiring structure 120 described above in the vertical direction (Z direction) to form an alignment inspection area AA. The alignment inspection area AA may be positioned adjacent to a corner of the second semiconductor chip 200 on a plane.

The second passivation layer 230 may be arranged on the second wiring structure 220. The second passivation layer 230 may be arranged between the second wiring structure 220 and the first passivation layer 130. The second passivation layer 230 may surround at least a portion of each of a side surface of the second bonding pad 232 and a side surface of a second inspection electrode 215 described below. The second bonding pad 232 may overlap the second wiring pattern 224 in the vertical direction (Z direction). The second bonding pad 232 may be electrically connected to the second wiring pattern 224.

The second bonding pad 232 may be in direct contact with the first bonding pad 132. The first bonding pad 132 and the second bonding pad 232 may include the same metal. In some example embodiments, the first bonding pad 132 and the second bonding pad 232 may include copper (Cu). The first bonding pad 132 and the second bonding pad 232 may be bonded by mutual diffusion of, for example, through a high temperature annealing process. The first bonding pad 132 and the second bonding pad 232 are not limited to copper and may include a material that may be bonded to each other (e.g., gold (Au)). That is, the second bonding pad 232 may be directly bonded (for example, made integral to one another) to the first bonding pad 132.

The second passivation layer 230 may be in direct contact with the first passivation layer 130. The first passivation layer 130 and the second passivation layer 230 may include the same material. In some example embodiments, the first passivation layer 130 and the second passivation layer 230 may include silicon oxide. The first passivation layer 130 and the second passivation layer 230 may be bonded to each other, for example, by a high-temperature annealing process, and may have a stronger bonding strength by covalent bonding between silicon and oxygen. The first passivation layer 130 and the second passivation layer 230 are not limited to silicon oxide and may include insulating materials (e.g., SiCN) that may be bonded to each other. That is, the second passivation layer 230 may be directly bonded to the first passivation layer 130. A bonding surface BS may be defined between the first passivation layer 130 and the second passivation layer 230.

Accordingly, the first semiconductor chip 100 and the second semiconductor chip 200 may be bonded to each other. That is, the first semiconductor chip 100 and the second semiconductor chip 200 may be bonded to each other by copper-copper (Cu—Cu) hybrid bonding. Therefore, according to a semiconductor package according to some example embodiments, gap-fill defects may be prevented or reduced by not requiring a gap-fill process for filling a gap between semiconductor chips. In addition, as the size of semiconductor packages decreases, a distance between solder balls decreases, which may result in defects such as adjacent solder balls bonding to each other. However, in the semiconductor package according to some example embodiments, since Cu—Cu hybrid bonding instead of solder balls is used, bonding defects of solder balls may be prevented or reduced and the thickness of the semiconductor package may be further reduced.

Referring to FIGS. 1 and 2A, the semiconductor package 10 according to some example embodiments may include the first alignment inspection structure AS1 and the second alignment inspection structure AS2 located in the alignment inspection area AA. FIG. 1 illustrates the planar shapes of the first alignment inspection structure AS1 and the second alignment inspection structure AS2 as squares, but example embodiments are not limited thereto. For example, the planar shape of each of the first alignment inspection structure AS1 and the second alignment inspection structure AS2 may be provided as a circle, an ellipse, or a polygon other than a square.

Referring to FIG. 2A, in an embodiment, the first alignment inspection structure AS1 may be arranged within the first semiconductor chip 100 and the first passivation layer 130, and the second alignment inspection structure AS2 may be arranged within the second semiconductor chip 200 and the second passivation layer 230. The first alignment inspection structure AS1 may include the first inspection electrode 115, and the second alignment inspection structure AS2 may include the second inspection electrode 215.

The first inspection electrode 115 may penetrate the first semiconductor substrate 110, the first wiring structure 120, and the first passivation layer 130. The first inspection electrode 115 may have, for example, a columnar shape extending in the vertical direction (Z direction). In other words, the first semiconductor substrate 110, the first wiring structure 120, and the first passivation layer 130 may surround the side surface of the first inspection electrode 115. The first inspection electrode 115 may be spaced apart from the first bonding pad 132, the first wiring pattern 124, and the first through electrode 114 in a horizontal direction (e.g., a direction perpendicular to the Z direction). In an embodiment, the first inspection electrode 115 may be electrically insulated from the first wiring pattern 124. The first inspection electrode 115 may not overlap the first connection terminal 105 in the vertical direction (Z direction). The first inspection electrode 115 and the first connection terminal 105 may be electrically insulated from each other.

A lower surface of the first inspection electrode 115 may be coplanar with a lower surface of the first semiconductor substrate 110, and an upper surface of the first inspection electrode 115 may be coplanar with an upper surface of the first passivation layer 130. In an embodiment, a thickness of the first inspection electrode 115 in the vertical direction (Z direction) may be greater than a thickness of the first through electrode 114 in the vertical direction (Z direction). In some example embodiments, the first inspection electrode 115 may be a through electrode.

The first inspection electrode 115 may include the same material as the first through electrode 114. For example, the first inspection electrode 115 may include a barrier film formed on a surface of the columnar shape thereof and a buried conductive layer filling the inside of the barrier film. The barrier film may include at least one of Ti, TiN, Ta, TaN, Ru, Co, Mn, WN, Ni, and NiB, but is not limited thereto. The buried conductive layer may include, but is not limited to, at least one of Cu, a Cu alloy such as CuSn, CuMg, CuNi, CuZn, CuPd, CuAu, CuRe, or CuW, W, W alloy, Ni, Ru, and Co.

The second inspection electrode 215 may penetrate the second semiconductor substrate 210, the second wiring structure 220, and the second passivation layer 230. The second inspection electrode 215 may have, for example, a columnar shape extending in the vertical direction (Z direction). In other words, the second semiconductor substrate 210, the second wiring structure 220, and the second passivation layer 230 may surround a side surface of the second inspection electrode 215. The second inspection electrode 215 may be spaced apart from the second bonding pad 232 and the second wiring pattern 224 in the horizontal direction (e.g., the direction perpendicular to the Z direction). In an embodiment, the second inspection electrode 215 may be electrically insulated from the second wiring pattern 224. In some example embodiments, the second inspection electrode 215 may be a through electrode. The second inspection electrode 215 may include the same material as the first inspection electrode 115.

The second inspection electrode 215 may be electrically connected to the first inspection electrode 115. That is, the first alignment inspection structure AS1 may be electrically connected to the second alignment inspection structure AS2. The second inspection electrode 215 may overlap the first inspection electrode 115 in the vertical direction (Z direction). The second inspection electrode 215 may be in direct contact with the first inspection electrode 115.

When stacking the second semiconductor chip 200 on the first semiconductor chip 100, it is necessary to check the alignment between the first semiconductor chip 100 and the second semiconductor chip 200. Typically, accuracy of alignment between the first semiconductor chip 100 and the second semiconductor chip 200 is calculated based on data measured before bonding or based on a destructive analysis of a sample chip after bonding.

FIG. 2A shows a case where the first semiconductor chip 100 is accurately aligned with the second semiconductor chip 200, and FIG. 2B shows a case where the first semiconductor chip 100 is misaligned with the second semiconductor chip 200.

In the semiconductor package 10 according to an embodiment, accuracy of alignment between the first semiconductor chip 100 and the second semiconductor chip 200 may be determined through the first inspection electrode 115 and the second inspection electrode 215. For example, by using a current-voltage curve (IV curve) measurement method, whether the first inspection electrode 115 and the second inspection electrode 215 are interconnected to each other may be electrically determined so as to obtain information on the alignment between the first semiconductor chip 100 and the second semiconductor chip 200.

Alternatively, the mutual alignment between the first inspection electrode 115 and the second inspection electrode 215 may be determined using a pico-second laser pulse inspection method, and information about the alignment between the first semiconductor chip 100 and the second semiconductor chip 200 may be obtained. Specifically, when a very short laser pulse of picosecond (10⁻¹²) units (e.g., 1-10 picoseconds) is applied to the second inspection electrode 215, ultrasonic waves generated by the laser pulse may travel along the second inspection electrode 215.

When the second inspection electrode 215 is normally aligned with the first inspection electrode 115, as in FIG. 2A, the ultrasonic waves may normally travel from the second inspection electrode 215 to the first inspection electrode 115. When the second inspection electrode 215 is not normally aligned with the first inspection electrode 115 (misaligned), various optical signals are generated, such as ultrasonic waves being reflected at a boundary surface (e.g., the bonding surface BS) between the second inspection electrode 215 and the first inspection electrode 115, and through this, it may be determined that the first semiconductor chip 100 is misaligned with the second semiconductor chip 200.

As such, as the semiconductor package 10 according to some example embodiments includes the first alignment inspection structure AS1 and the second alignment inspection structure AS2, not only are electrical inspection and optical inspection of alignment between chips easy as described above, but also, unlike image inspection using infrared (IR), a structural design avoiding a metal layer may not be required. That is, the structural design for alignment inspection may be easy. Accordingly, product reliability of the semiconductor package 10 may be improved because the first semiconductor chip 100 and the second semiconductor chip 200 are precisely aligned and bonded.

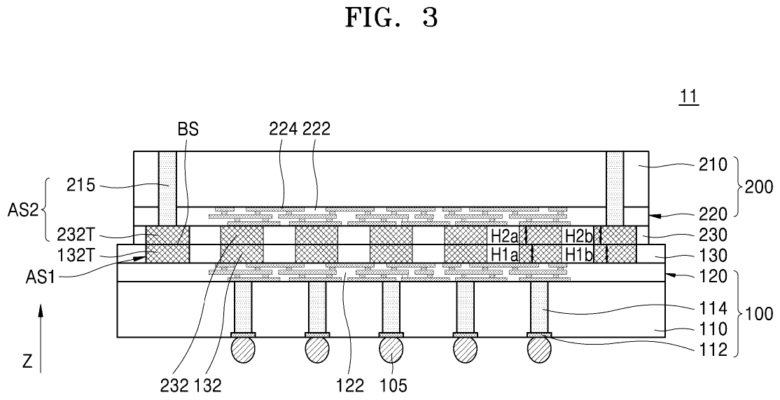

FIG. 3 is a schematic cross-sectional view to describe a semiconductor package according to some example embodiments. In FIG. 3, the same reference numbers as those of FIG. 2A indicate substantially the same components, so a description thereof will be omitted and description will focus on the differences.

Referring to FIG. 3, the first alignment inspection structure AS1 of a semiconductor package 11 may include a first inspection pad 132T, and the second alignment inspection structure AS2 of the semiconductor package 11 may include a second inspection pad 232T and the second inspection electrode 215.

The first inspection pad 132T may penetrate the first passivation layer 130. In other words, the first passivation layer 130 may surround a side surface of the first inspection pad 132T. The first inspection pad 132T may be spaced apart from the first bonding pad 132 in a horizontal direction (e.g., in an X direction and/or Y direction of FIG. 1). The first inspection pad 132T may be electrically insulated from the first wiring structure 120. A thickness H1b of the first inspection pad 132T may be the same or substantially the same as a thickness H1a of the first bonding pad 132. The first inspection pad 132T may include the same material as the first bonding pad 132.

The second inspection pad 232T may penetrate the second passivation layer 230. In other words, the second passivation layer 230 may surround a side surface of the second inspection pad 232T. The second inspection pad 232T may be spaced apart from the second bonding pad 232 in the horizontal direction (e.g., in the X direction and/or Y direction of FIG. 1). The second inspection pad 232T may be electrically insulated from the second wiring structure 220. A thickness H2b of the second inspection pad 232T may be the same or substantially the same as a thickness H2a of the second bonding pad 232. The second inspection pad 232T may include the same material as the second bonding pad 232.

The second inspection pad 232T may overlap the first inspection pad 132T in the vertical direction (Z direction). The second inspection pad 232T may be in direct contact with the first inspection pad 132T. The second inspection pad 232T may be electrically connected to the first inspection pad 132T. A bonding surface between the second inspection pad 232T and the first inspection pad 132T may be identical or substantially identical to the bonding surface BS.

The second inspection electrode 215 may penetrate the second semiconductor substrate 210 and the second wiring structure 220. The second inspection electrode 215 may have, for example, a columnar shape extending in the vertical direction (Z direction). In other words, the second semiconductor substrate 210 and the second wiring structure 220 may surround a side surface of the second inspection electrode 215. The second inspection electrode 215 may be spaced apart from the second wiring pattern 224 in the horizontal direction (e.g., the direction perpendicular to the Z direction). In an embodiment, the second inspection electrode 215 may be electrically insulated from the second wiring pattern 224. In some example embodiments, the second inspection electrode 215 may be a through electrode. The second inspection electrode 215 may include the same material as the first inspection electrode 115.

The second inspection electrode 215 may be electrically connected to the second inspection pad 232T. The second inspection electrode 215 may overlap the second inspection pad 232T in the vertical direction (Z direction). The second inspection electrode 215 may be in direct contact with the second inspection pad 232T.

According to some example embodiments, the product reliability of the semiconductor package 11 may be improved by precisely aligning the first semiconductor chip 100 and the second semiconductor chip 200 through an electrical inspection method and an optical inspection method by using the first alignment inspection structure AS1 including the first inspection pad 132T and the second alignment inspection structure AS2 including the second inspection pad 232T and the second inspection electrode 215.

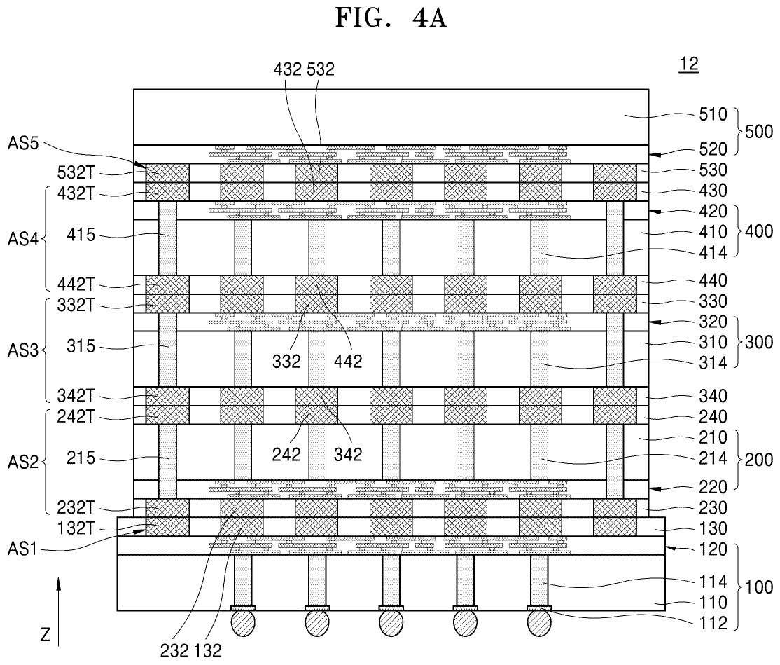

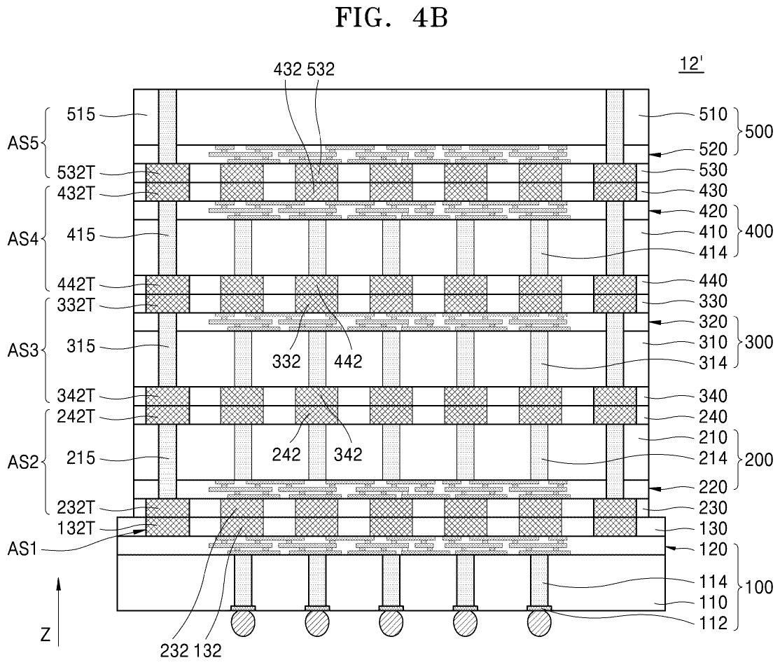

FIGS. 4A and 4B are schematic cross-sectional views to describe semiconductor packages 12 and 12′according to some example embodiments. In FIGS. 4A and 4B, the same reference numerals as those in FIG. 3 indicate substantially the same configuration, so a description thereof will be omitted and description will focus on the differences.

Referring to FIG. 4A, the semiconductor package 12 according to some example embodiments may further include a second back passivation layer 240, a second back bonding pad 242, a third back passivation layer 340, a third back bonding pad 342, a third semiconductor chip 300, a third passivation layer 330, a fourth back passivation layer 440, a fourth back bonding pad 442, a fourth semiconductor chip 400, a fourth passivation layer 430, a fourth bonding pad 432, a fifth passivation layer 530, a fifth bonding pad 532, and a fifth semiconductor chip 500.

Additionally, the semiconductor package 12 may include first to fifth alignment inspection structures AS1 to AS5. The first alignment inspection structure AS1 may include the first inspection pad 132T. The second alignment inspection structure AS2 may include the second inspection pad 232T, the second inspection electrode 215, and the second back inspection pad 242T. The third alignment inspection structure AS3 may include a third back inspection pad 342T, a third inspection electrode 325, and a third inspection pad 332T. The fourth alignment inspection structure AS4 may include a fourth back inspection pad 442T, a fourth inspection electrode 415, and a fourth inspection pad 432T. The fifth alignment inspection structure AS5 may include a fifth inspection pad 532T.

The second back passivation layer 240 may surround a side surface of the second back bonding pad 242 and a side surface of the second back inspection pad 242T. The third back passivation layer 340 may surround a side surface of the third back bonding pad 342 and a side surface of the third back inspection pad 342T. The third passivation layer 330 may surround a side surface of the third bonding pad 332 and a side surface of the third inspection pad 332T. The fourth back passivation layer 440 may surround a side surface of the fourth back bonding pad 442 and a side surface of the fourth back inspection pad 442T. The fourth passivation layer 430 may surround a side surface of the fourth bonding pad 432 and a side surface of the fourth inspection pad 432T. The fifth passivation layer 530 may surround a side surface of the fifth bonding pad 532 and a side surface of the fifth inspection pad 532T.

A second through electrode 214 may penetrate the second semiconductor substrate 210 and be electrically connected to the second wiring structure 220 and the second back bonding pad 242. A third through electrode 314 may penetrate the third semiconductor substrate 310 and be electrically connected to the third wiring structure 320 and the third back bonding pad 342. A fourth through electrode 414 may penetrate the fourth semiconductor substrate 410 and be electrically connected to the fourth wiring structure 420 and the fourth back bonding pad 442.

The third inspection electrode 315 may penetrate the third semiconductor substrate 310 and the third wiring structure 320 and be electrically connected to the third back inspection pad 342T and the third inspection pad 332T. The fourth inspection electrode 425 may penetrate the fourth semiconductor substrate 410 and the fourth wiring structure 420 and be electrically connected to the fourth back inspection pad 442T and the fourth inspection pad 432T.

The third inspection electrode 315 may overlap the third back inspection pad 342T and the third inspection pad 332T in the vertical direction (Z direction). The fourth inspection electrode 425 may overlap the fourth back inspection pad 442T and the fourth inspection pad 432T in the vertical direction (Z direction).

The third wiring structure 320 may be arranged on the third semiconductor substrate 310. The third wiring structure 320 may include a third wiring pattern 324. The third wiring pattern 324 may be sequentially stacked from an upper surface of the third semiconductor substrate 310.

The fourth wiring structure 420 may be arranged on the fourth semiconductor substrate 410. The fourth wiring structure 420 may include a fourth wiring pattern 424. The fourth wiring pattern 424 may be sequentially stacked from an upper surface of the fourth semiconductor substrate 410.

The fifth wiring structure 520 may include a fifth wiring pattern 524. The fifth wiring pattern 524 may be sequentially stacked from a lower surface of the fifth semiconductor substrate 510.

The first to fifth semiconductor chips 100, 200, 300, 400, and 500 may be memory semiconductor chips. Examples of the memory semiconductor chips may include a volatile memory semiconductor chip, such as, for example, DRAM or SRAM, or a nonvolatile memory semiconductor chip, such as PRAM, MRAM, FeRAM, or RRAM. The first semiconductor chip 100 may be, for example, a buffer semiconductor chip.

In some example embodiments, the first semiconductor chip 100 may be a logic semiconductor chip, and the second to fifth semiconductor chips 200, 300, 400, and 500 may be memory semiconductor chips. The first semiconductor chip 100 may be a controller semiconductor chip that controls the input/output operations of the second to fifth semiconductor chips 200, 300, 400, and 500 that are electrically connected to the first semiconductor chip 100.

Referring to FIG. 4A, the semiconductor package 12 according to some example embodiments includes three or more alignment inspection structures (e.g., the first to fifth alignment inspection structures AS1 to AS5), alignment may be identified by an electrical method and/or an optical method, and thus, alignment between three or more stacked semiconductor chips may be inspected.

Referring to FIG. 4B, the fifth alignment inspection structure AS5 may further include a fifth inspection electrode 515. In an embodiment, the fifth inspection electrode 515 may penetrate the fifth semiconductor substrate 510 to be exposed to the outside. Accordingly, alignment between semiconductor chips may be inspected even after stacking of the semiconductor chips is completed.

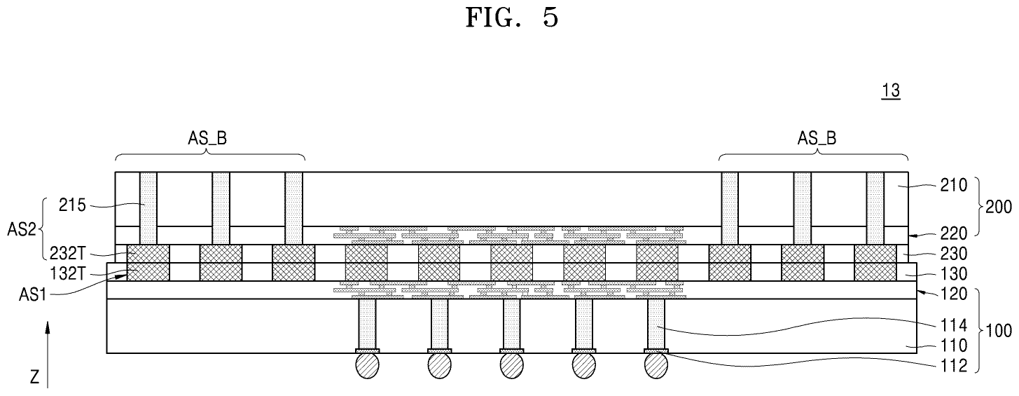

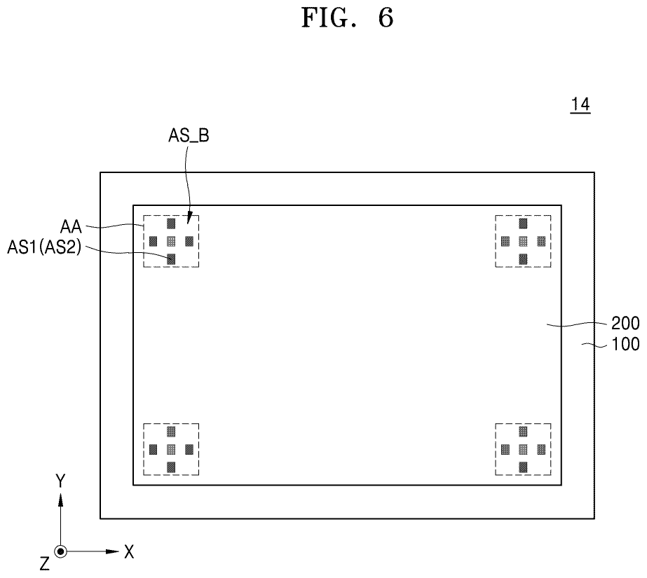

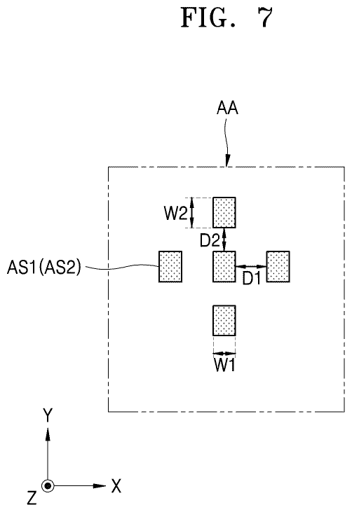

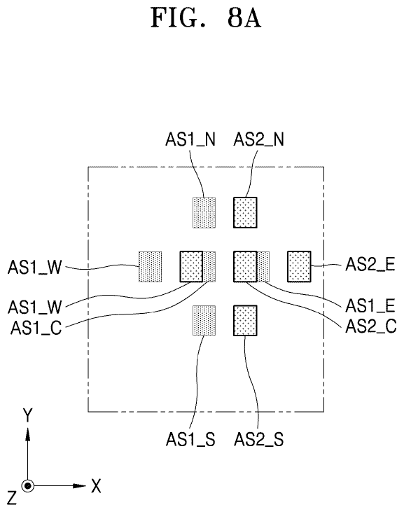

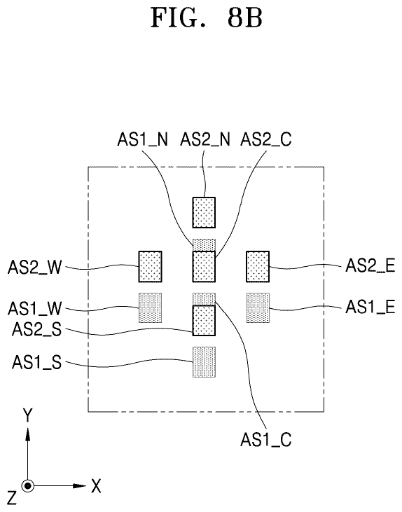

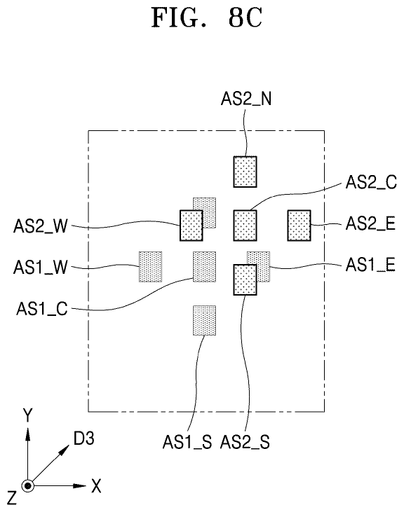

FIG. 5 is a schematic cross-sectional view to describe a semiconductor package 13 according to some example embodiments, FIG. 6 is a schematic plan view to describe a semiconductor package 14 according to some example embodiments, and FIG. 7 is a schematic enlarged plan view to describe the semiconductor package 14 according to some example embodiments. FIG. 7 is an enlarged view of the alignment inspection area AA of FIG. 6. FIGS. 8A, 8B, and 8C are schematic enlarged plan views to describe semiconductor packages according to some example embodiments.

Referring to FIG. 5, the semiconductor package 13 according to an embodiment may include an alignment inspection structure bundle AS_B. The alignment inspection structure bundle AS_B may include a plurality of first alignment inspection structures AS1 and a plurality of second alignment inspection structures AS2. The plurality of first alignment inspection structures AS1 and the plurality of second alignment inspection structures AS2 respectively corresponding to the plurality of first alignment inspection structures AS1 may form the alignment inspection structure bundle AS_B.

In an embodiment, the plurality of first alignment inspection structures AS1 may be arranged horizontally adjacent to each other, and the plurality of second alignment inspection structures AS2 may be arranged horizontally adjacent to each other. For example, a plurality of second inspection electrodes 215 included in the plurality of second alignment inspection structures AS2 may be arranged adjacent to each other in a horizontal direction.

Referring to FIG. 6, the alignment inspection structure bundle AS_B included in the semiconductor package 14 according to some example embodiments may be located in the alignment inspection area AA. The alignment inspection area AA may be located at a corner of the second semiconductor chip 200 on a plane. Although FIG. 6 illustrates that the semiconductor package 14 includes four alignment inspection structure bundles AS_B, example embodiments are not limited thereto. In an embodiment, three or less or five or more alignment inspection structure bundles AS_B may be provided.

The first alignment inspection structure AS1 illustrated in FIGS. 6, 7, and 8A to 8C may be a first inspection pad (132T, see FIG. 3) or a first inspection electrode (115, see FIG. 2A) included therein, and the second alignment inspection structure AS2 may be a second inspection pad (232T, see FIG. 3) or a second inspection electrode (215, see FIG. 2B) included therein. For example, in FIGS. 6, 7, and 8A to 8C, when the first alignment inspection structure AS1 is understood to be the first inspection pad (132T, see FIG. 3), the second alignment inspection structure AS2 may be understood to be the second inspection pad (232T, see FIG. 3). When the first alignment inspection structure AS1 is understood to be a first inspection electrode (115, see FIG. 2A), the second alignment inspection structure AS2 may be understood to be a second inspection electrode (215, see FIG. 2A). For example, in the description below, a distance between the first alignment inspection structures AS1 may refer to a distance between the first inspection pads 132T, and in this case, a distance between the second alignment inspection structures AS2 may refer to a distance between the second inspection pads 232T. Similarly, in the description below, the distance between the first alignment inspection structures AS1 may refer to a distance between the first inspection electrodes 115, and in this case, the distance between the second alignment inspection structures AS2 may refer to a distance between the second inspection electrodes 215.

First, referring to FIG. 7, the first alignment inspection structure AS1 and the second alignment inspection structure AS2 may be provided in plurality. The first alignment inspection structure AS1 may be arranged in a first direction (X direction) and/or a second direction (Y direction). The second alignment inspection structure AS2 may be arranged in the first direction (X direction) and/or the second direction (Y direction). FIG. 7 illustrates that the first alignment inspection structure AS1 is precisely aligned with the second alignment inspection structure AS2.

In an embodiment, a first distance D1 between adjacent first alignment inspection structures AS1 in the first direction (X direction) may be equal to or less than three times a first horizontal width W1 of the first alignment inspection structures AS1. A second distance D2 between adjacent first alignment inspection structures AS1 in the second direction (Y direction) may be equal to or less than three times a second horizontal width W2 of the first alignment inspection structures AS1. In an embodiment, the second alignment inspection structure AS2 may completely vertically overlap the first inspection structure AS1. The first distance D1 between adjacent second alignment inspection structures AS2 in the first direction (X direction) may be equal to or less than three times the first horizontal width W1 of the second alignment inspection structures AS2. The second distance D2 between adjacent second alignment inspection structures AS2 in the second direction (Y direction) may be equal to or less than three times the second horizontal width W2 of the first alignment inspection structure AS2.

As the semiconductor packages 13 and 14 according to some example embodiments include the alignment inspection structure bundle AS_B, a misalignment direction of the first semiconductor chip 100 and the second semiconductor chip 200 may be identified using results of the electrical inspection and/or optical inspection described above.

Referring to FIG. 8A, if the second semiconductor chip 200 is tilted to the right (+X direction) from the first semiconductor chip 100, a second upper structure AS2_N, a second right structure AS2_E, and a second lower structure AS2_S may not respectively overlap with a first upper structure AS1_N, a second right structure AS1_E, and a first lower structure AS1_S, which they respectively correspond to, in the vertical direction (Z direction).

Accordingly, an output of a test signal (electrical signal or optical signal) applied to the second upper structure AS2_N, the second right structure AS2_E, and the second lower structure AS2_S may be determined as a defective one. In contrast, an output of a test signal applied to a second center structure AS2_C and a second left structure AS2_W may be determined to be normal because the second center structure AS2_C and the second left structure AS2_W are connected to the first right structure AS1_E and the first center structure AS1_C, respectively. Through this, a direction of tilt of the second semiconductor chip 200 may be predicted to be a direction to the right.

Similarly, referring to FIG. 8B, if the second semiconductor chip 200 is tilted upward (in the +Y direction) from the first semiconductor chip 100, the second upper structure AS2_N, the second left structure AS2_W, and the second right structure AS2_E may not respectively overlap with the first upper structure AS1_N, a first left structure AS1_W, and the first right structure AS1_E, which they respectively correspond to, in the vertical direction (in the Z direction).

Accordingly, an output of a test signal applied to the second upper structure AS2_N, the second left structure AS2_W, and the second right structure AS2_E may be determined as a defective one. In contrast, an output of a test signal applied to the second center structure AS2_C and the second lower structure AS2_S may be determined to be normal because the second center structure AS2_C and the second lower structure AS2_S are connected to the first upper structure AS1_N and the first center structure AS1_C, respectively. Through this, the tilting direction of the second semiconductor chip 200 may be identified to be upward.

Referring to FIG. 8C, if the second semiconductor chip 200 is tilted in a diagonal direction D3 from the first semiconductor chip 100, the second upper structure AS2_N, the second center structure AS2_C, and the second right structure AS2_E may not respectively overlap with the first upper structure AS1_N, the first center structure AS1_C, and the first right structure AS1_E, which they respectively correspond to, in the vertical direction (Z direction).

Accordingly, an output of the test signal applied to the second upper structure AS2_N, the second center structure AS2_C, and the second right structure AS2_E may be determined as a defective one. In contrast, an output of the test signal applied to the second left structure AS2_W and the second lower structure AS2_S may be determined to be normal because the second left structure AS2_W and the second lower structure AS2_S are connected to the first upper structure AS1_N and the first right structure AS1_E, respectively. Through this, the tilting direction of the second semiconductor chip 200 may be identified to be an upper right direction.

For simplicity, FIGS. 6, 7, and 8A to 8C illustrate that one alignment inspection structure bundle AS_B includes five first alignment inspection structures AS1 and five second alignment inspection structures AS2, but example embodiments are not limited thereto. The numbers of the first alignment inspection structures AS1 and the second alignment inspection structures AS2 included in one alignment inspection structure bundle AS_B may be four or less or six or more.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10 %) around the stated numerical values or shapes.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a first semiconductor chip comprising a first semiconductor substrate and a first wiring structure including a first wiring pattern and a first wiring insulating film;
a second semiconductor chip comprising a second semiconductor substrate and a second wiring structure including a second wiring pattern and a second wiring insulating film;
a first bonding pad on the first wiring structure;
a first passivation layer surrounding a side surface of the first bonding pad;
a second bonding pad electrically connected to the first bonding pad;
a second passivation layer surrounding a side surface of the second bonding pad;
a first alignment inspection structure horizontally apart from the first wiring pattern and penetrating the first passivation layer; and
a second alignment inspection structure vertically penetrating the second semiconductor substrate, the second wiring insulating film, and the second passivation layer.

2. The semiconductor package of claim 1, wherein the second alignment inspection structure is horizontally apart from the second wiring pattern and vertically overlaps the first alignment inspection structure.

3. The semiconductor package of claim 1, wherein the first alignment inspection structure is on the first wiring structure and includes a first inspection pad in contact with the second alignment inspection structure.

4. The semiconductor package of claim 3, wherein the second alignment inspection structure is on the second wiring structure and includes a second inspection pad in contact with the first alignment inspection structure.

5. The semiconductor package of claim 4, wherein
a thickness of the first inspection pad is a same thickness as a thickness of the first bonding pad, and
a thickness of the second inspection pad is a same thickness as a thickness of the second bonding pad.

6. The semiconductor package of claim 4, wherein the second alignment inspection structure includes a second inspection electrode penetrating the second semiconductor substrate and the second wiring insulating film and in contact with the second inspection pad.

7. The semiconductor package of claim 1, wherein
the first alignment inspection structure includes a first inspection electrode vertically penetrating the first semiconductor substrate, the first wiring insulating film, and the first passivation layer, and
the second alignment inspection structure includes a second inspection electrode vertically penetrating the second semiconductor substrate, the second wiring insulating film, and the second passivation layer and is in contact with the first inspection electrode.

8. The semiconductor package of claim 7, further comprising:
a first through electrode penetrating the first semiconductor substrate and electrically connected to the first wiring structure; and
a connection terminal below the first through electrode,
wherein a thickness of the first inspection electrode is greater than a thickness of the first through electrode.

9. The semiconductor package of claim 1, wherein
the first alignment inspection structure comprises a first left structure, a first center structure, and a first right structure in a first direction, and
the second alignment inspection structure includes a second left structure, a second center structure, and a second right structure in the first direction.

10. The semiconductor package of claim 9, wherein
the first alignment inspection structure comprises a first upper structure, a first center structure, and a first lower structure in a second direction perpendicular to the first direction, and
the second alignment inspection structure comprises a second upper structure, a second center structure, and a second lower structure in the second direction.

11. A semiconductor package comprising:
a first semiconductor chip comprising a first semiconductor substrate and a first wiring structure;
a second semiconductor chip comprising a second semiconductor substrate and a second wiring structure;
a first bonding pad and a first inspection pad on the first wiring structure;
a first passivation layer surrounding a side surface of the first bonding pad and a side surface of the first inspection pad;
a second bonding pad electrically connected to the first bonding pad and a second inspection pad electrically connected to the first inspection pad;
a second passivation layer surrounding a side surface of each of the second bonding pad and the second inspection pad; and
a second inspection electrode penetrating the second wiring structure and the second semiconductor substrate and in direct contact with the second inspection pad.

12. The semiconductor package of claim 11, wherein the first inspection pad and the first bonding pad include a same material, and the second inspection pad and the second bonding pad include a same material.

13. The semiconductor package of claim 11, wherein
the first bonding pad is electrically connected to the first wiring structure, and
the first inspection pad is electrically insulated from the first wiring structure.

14. The semiconductor package of claim 11, wherein
the second bonding pad is electrically connected to the second wiring structure, and
the second inspection pad is electrically insulated from the second wiring structure.

15. The semiconductor package of claim 11, wherein
the second inspection electrode is provided in plurality, and
a distance between adjacent second inspection electrodes is equal to or less than three times a horizontal width of each second inspection electrode.

16. The semiconductor package of claim 15, wherein, on a plane, the second inspection electrodes are spaced apart in a first direction and a second horizontal direction perpendicular to the first direction.

17. A semiconductor package comprising:
a first semiconductor chip comprising a first semiconductor substrate and a first wiring structure including a first wiring pattern and a first wiring insulating film;
a second semiconductor chip stacked on the first semiconductor chip and comprising a second semiconductor substrate and a second wiring structure, the second wiring structure comprising a second wiring pattern and a second wiring insulating film;
a first bonding pad on the first semiconductor chip and a first passivation layer surrounding the first bonding pad;
a second bonding pad on the second semiconductor chip opposite to the first bonding pad, and a second passivation layer surrounding the second bonding pad;
a first inspection electrode vertically penetrating the first semiconductor substrate, the first wiring structure, and the first passivation layer; and
a second inspection electrode vertically penetrating the second semiconductor substrate, the second wiring structure, and the second passivation layer, and electrically connected to the first inspection electrode.

18. The semiconductor package of claim 17, wherein
the first inspection electrode and the second inspection electrode are each provided in plurality,
a distance between adjacent first inspection electrodes is equal to or less than three times a horizontal width of each first inspection electrode, and
a distance between adjacent second inspection electrodes is equal to or less than three times a horizontal width of each second inspection electrode.

19. The semiconductor package of claim 17, wherein
the first inspection electrode is spaced horizontally apart from the first wiring pattern, and
the second inspection electrode is spaced horizontally apart from the second wiring pattern.

20. The semiconductor package of claim 17, wherein the second inspection electrode is at a corner of the second semiconductor chip.
